(19) United States
(12) Patent Application Publication
(10) Pub. No.: US 2020/0119476 A1
(43) Pub. Date: Apr. 16, 2020

(54) DISPLAY ASSEMBLY AND DISPLAY DEVICE

(71) Applicants: HKC CORPORATION LIMITED, Shenzhen, Guangdong (CN); CHONGOING HKC OPTELECTRONICS TECHNOLOGY CO., LTD., Chongqing (CN)

(72) Inventors: Shuixiu Hu, Chongqing (CN); Dongsheng Guo, Chongqing (CN)

(21) Appl. No.: 16/312,877

(22) PCT Filed: Nov. 21, 2018
(86) PCT No.: PCT/CN2018/116668

§ 371 Date: Dec. 21, 2018

(30) Foreign Application Priority Data
Oct. 16, 2018 (CN) 201821673585.3

(51) Int. Cl. H01R 12/73; H05K 1/14; H05K 1/11; H01R 13/627

(52) U.S. Cl. CPC H01R 12/732; H05K 1/144; H05K 1/117; H05K 2201/10128; H05K 2201/10333; H05K 2201/10681; H05K 2201/09063; H01R 13/6271

(57) ABSTRACT

A display assembly. The display assembly includes: a display panel, including: a display area and a peripheral circuit area arranged at an outer periphery of the display area; wherein the peripheral circuit area is provided with a driver circuit; a driver chip package, the driver chip package having a first end and a second end that are opposite to each other, and the first end being in electrical connection with the driver circuit; a circuit board; and a connector. The circuit board is in connection with the second end of the driver chip package via the connector.

### CROSS-REFERENCE TO RELATED APPLICATIONS

This application is the International Application No. PCT/CN2018/116668 for entry into US national phase with an international filing date of Nov. 21, 2018, designating US, now pending, and claims priority to Chinese Patent Application No. 201821673585.3, filed on Oct. 16, 2018, the content of which is incorporated herein by reference in its entirety.

### BACKGROUND OF THE INVENTION

### Field of the Invention

The present application relates to the technical field of display devices, and more particularly to a display assembly and a display device.

### Description of Related Art

The statements herein merely provide background information relating to the present application and do not necessarily constitute prior art. In assembling of a common display device, such as a liquid crystal display, it is required to assemble a display panel, a chip-on-film (COF) package, and a printed circuit board packed with components (printed circuit board+assembly, PCBA) together, which are generally connected in a binding manner. When the PCBA requires for modification, the display panel needs to be replaced at the same time. Moreover, because the yield and efficiency of the rework of the binding technology are relatively low, resulting in greatly reduced flexibility of the PCBA.

### BRIEF SUMMARY OF THE INVENTION

It is an object of the present application to provide a display assembly, which aims at, comprising but not limited to, improving the flexibility of assembling/disassembling of the circuit board.

Technical solutions adopted by embodiments of the present application are as follows: a display assembly, comprises:

a display panel, comprising: a display area and a peripheral circuit area arranged at an outer periphery of the display area; wherein the peripheral circuit area is provided with a driver circuit;

a driver chip package, the driver chip package having a first end and a second end that are opposite to each other, and the first end being in electrical connection with the driver circuit;

a circuit board; and a connector.

The circuit board is in connection with the second end of the driver chip package via the connector.

In one embodiment, the connector comprises: a female connection member, connected at the second end of the driver chip package; and a male connection member, connected at one end of the circuit board opposite to the driver chip package. The male connection member and the female connection member are configured to fit each other to form pluggable connection.

In one embodiment, the female connection member comprises bosses arranged at a surface of the second end, and the bosses are configured to be inserted into the male connection member for electrical connection.

In one embodiment, the second end defines therein at least one notch, a projection is arranged at a position of the male connection member corresponding to a position of the respective notch, and the projection snap-fits into the respective notch.

In one embodiment, the at least one notches are symmetrically arranged at two sides of the second end in a width direction.

In one embodiment, a section of the respective notch is arc.

In one embodiment, a section of the respective notch is semispherical.

In one embodiment, a section of the respective notch is rectangular.

In one embodiment, the connector comprises: a female connection member, arranged at one end of the circuit board opposite to the driver chip package; and a male connection member, arranged at the second end of the driver chip package. The male connection member and the female connection member are configured to fit each other to form pluggable connection.

In one embodiment, the female connection member comprises bosses arranged at a surface of the circuit board, and electrical connection between the driver chip package and the circuit board is realized through the fitting and the pluggable connection between the bosses and the male connection member.

In one embodiment, the display assembly comprises a plurality of the circuit boards, and a plurality of the driver chip packages are arranged between the respective circuit board and the display panel.

In one embodiment, the plurality of the driver chip packages are equally spaced apart at the same circuit board.

In one embodiment, the plurality of the circuit boards are arranged at the same side of the display panel and equally spaced apart from adjacent ones.

In one embodiment, the driver chip package is a chip-on-film package.

In one embodiment, the driver chip package is a tape carrier package.

In one embodiment, the display panel is a thin film transistor-liquid crystal display, an active matrix liquid crystal display, a surface conduction electron emitter display panel, a plasma display panel, or an organic luminescence display panel.

It is another object of the present application to provide a display device, which comprises:

a display panel, comprising: a display area and a peripheral circuit area arranged at an outer periphery of the display area; wherein the peripheral circuit area is provided with a driver circuit;

a driver chip package, the driver chip package having a first end and a second end that are opposite to each other, and the first end being in electrical connection with the driver circuit; and

a circuit board; and a connector. The circuit board is in connection with the second end of the driver chip package via the connector.

It is still another object of the present application to provide a display device, which comprises:

a display panel, comprising: a display area and a peripheral circuit area surrounding the display area; wherein a surface of the peripheral circuit area is provided with a driver circuit;

a plurality of chip-on-film packages, with each chip-on-film package having a first end and a second end that are opposite to each other, and the first end being in electrical connection with the driver circuit; and

a plurality of circuit boards; and a plurality of connectors. At least one of the plurality of chip-on-film packages is connected between the respective circuit board and the display panel. The second end of each chip-on-film package is connected with the respective circuit board via the respective connector.

In the display assembly provided by embodiments of the present application, when it is required for modification, the removal and the insertion of the circuit board is directly conducted with respect to the connector 400 for replacement with the new circuit board, and it is not necessary to replace with new display panel for assembly. In this way, the product utilization is greatly improved, the production cost can be lowered, and the product yield is improved.

### BRIEF DESCRIPTION OF THE DRAWINGS

In order to more clearly illustrate the technical solution in embodiments of the present application, the following drawings, which are to be used in the description of the embodiments or the existing techniques, will be briefly described. It will be apparent that the drawings described in the following description are merely embodiments of the present application. Other drawings may be obtained by those skilled in the art without paying creative labor.

FIG. 1 is an explosive structural schematic view of a display assembly provided by one embodiment of the present application;

FIG. 2 is a front schematic view of a display panel of a display assembly of FIG. 1;

FIG. 3 is a partial explosive schematic view of a display assembly provided by one embodiment;

FIG. 4 is a partial explosive schematic view of a display assembly provided by another embodiment; and

FIG. 5 is a front schematic view of a display assembly provided by one embodiment.

### DETAILED DESCRIPTION OF THE EMBODIMENTS

In order to make the technical problems to be solved, technical solutions, and beneficial effects of the present application more clear, the present application will be further described in detail hereinbelow with reference to the accompanying drawings and embodiments. It should be understood that the specific embodiments described herein are merely intended to explain the application rather than to limit the present application.

It should be noted that when an element is referred to as being “fixed” or “arranged” at/in/on another element, it can be directly at/in/on the other element. When an element is referred to as being “connected” to/with the another element, it can be directly or indirectly connected to/with the other element. It should be understood that terms “top”, “bottom”, “left”, “right”, and the like indicating orientation or positional relationship are based on the orientation or the positional relationship shown in the drawings, and are merely for facilitating the description of the present application, rather than indicating or implying that a device or component must have a particular orientation, or be configured or operated in a particular orientation, and thus should not be construed as limiting the application; and the specific meaning of the above terms can be understood by those skilled in the art according to specific circumstances. Moreover, the terms “first” and “second” are adopted for descriptive purposes only and are not to be construed as indicating or implying a relative importance or implicitly indicating the number of technical features indicated. Thus, features defining “first” and “second” may include one or more of the features either explicitly or implicitly. In the description of the present application, the meaning of “a plurality of” or “multiple” is two or more unless otherwise particularly defined.

In order to explain technical solutions described in the present application, the following detailed description will be made with reference to the drawings and embodiments.

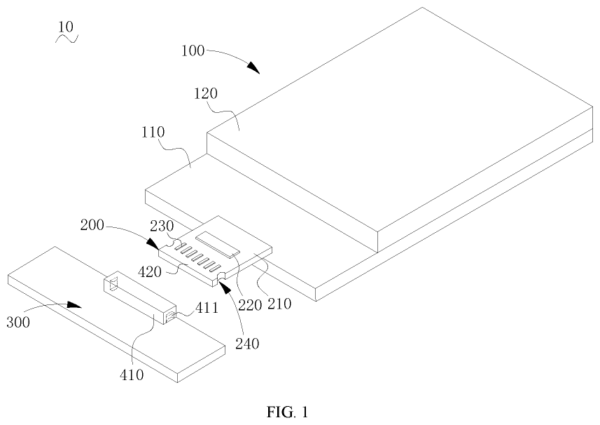

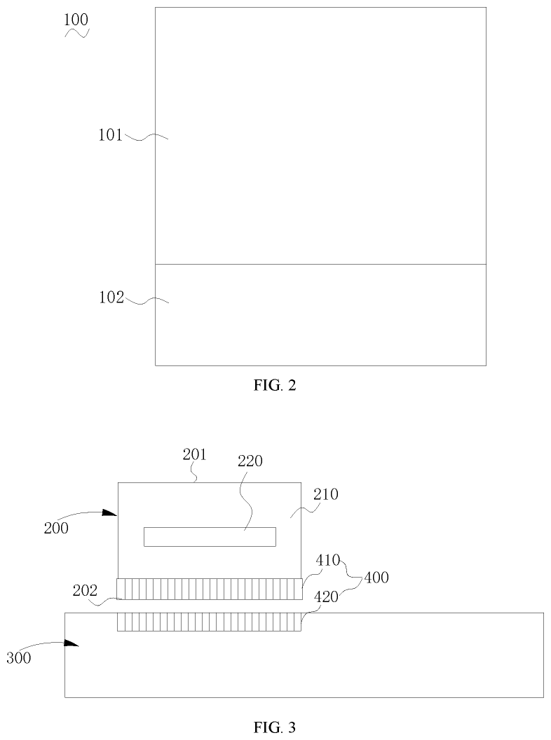

As shown in FIGS. 1-3, a display assembly 10 provided by one embodiment of the present application includes: a display panel 100, a driver chip package 200, a circuit board 300, and a connector 400. As shown in FIGS. 2-3, the display panel 100 includes: a display area 101 and a peripheral circuit area 102 arranged at an outer periphery of the display area 101. The peripheral circuit area 102 is provided with a driver circuit, and the driver circuit is configured to drive the circuit board 300, that is, the driver circuit at the outer periphery is capable of driving the display area 101 to display images. As shown in FIGS. 1-2, the driver chip package 200 has a first end 201 and second end 202 that are opposite to each other, the first end 201 is connected with a surface of the peripheral circuit area 102, and the first end 201 is in electrical connection with the driver circuit of the display panel 100, and the second end 202 is configured to realize electrical connection with the circuit board 300 by pluggable connection of the second end 202 into the connector 400. Because the connector 400 is configured for connection, when the printed circuit needs to be modified, the insertion and removal operation of the printed circuit greatly improves the efficiency and convenience, and it is not necessary to replace with new display panel 100 for assembly.

In the display assembly 10 provided in this embodiment, because the connector 400 is adopted to connect between the driver chip package 200 and the circuit board 300, it is convenient for the operation in case of modification of the circuit board 300. When it is required for modification, the removal and the insertion of the circuit board is directly conducted with respect to the connector 400 for replacement with the new circuit board, and it is not necessary to replace with new display panel for assembly. In this way, the product utilization is greatly improved, the production cost can be lowered, and the product yield is improved.

The display panel 100 may be a thin film transistor-liquid crystal display (TFT-LCD), an active matrix liquid crystal display (AM-LCD), a surface conduction electron emitter display (SED) panel, a plasma display panel (PDP), or an organic luminescence (EL) display panel. The circuit board 300 may be a printed circuit board (PCB) or the circuit board packed with components (Printed Circuit Board+Assembly, PCBA).

In one embodiment, the display panel 100 is a TFT-LCD, the circuit board 300 is a hard PCB, sections of the TFT-LCD and the PCB are respectively rectangular, one side of the display panel 100 adjacent to a bottom thereof is provided with the peripheral circuit area 102. As shown in FIG. 5, the peripheral circuit area 102 is in connection with two circuit boards 300, and the two circuit boards 300 are spaced apart from each other. Four COF packages are connected between the respective circuit board 300 and the peripheral circuit area 102 of the display panel 100, that is, each of the COF packages is connected to the respective circuit board 300 via one connector 400 to realize the electrical connection.

In one embodiment, as shown in FIGS. 1-2, the display panel 100 includes a first substrate 110 and a second substrate 120. Both sections of the first substrate 110 and the second substrate 120 that are perpendicular to a display plane are rectangular. A surface area of the first substrate 110 is greater than a surface area of the second substrate 120. One side of the first substrate 110 has a protruding portion relative to the second substrate 120. The display area 101 of the display panel 100 is disposed at the second substrate 120, and the peripheral circuit area 102 is disposed at a region of the first substrate 110 exposing from the second substrate 120, that is, the peripheral circuit area 102 is arranged at the protruding portion.

In one embodiment, the display area 101 includes: a plurality of gate lines, a plurality of data lines, and a plurality of pixels (not shown in the figures). The plurality of pixels are located in a matrix formed by the gate lines and the data lines. The driver circuit of the peripheral circuit area 102 controls an illumination state of each pixel, and a particular image is displayed on the display panel 100 by different illumination states of the pixels. The driver circuit and a pad in connection with the driver circuit are formed at a surface of the protruding portion of the first substrate 110, and the second substrate 120 is connected with the surface of the first substrate 110, such that the pixels, the gate lines, and the data lines are sealed with respect to the external. A surface of the second substrate 120 is further provided with a polarizing film (not shown in the figures) so as to suppress or reduce the reflection of external light.

In one embodiment, the driver chip package 200 can be a COF package or a tape carrier package (TCP). Compared with other kinds of packages, the COF package or the TCP package has better reliability. In one embodiment, the driver chip package 200 is a COF package including a base diaphragm 210 and an integrated circuit chip 220 formed on the base diaphragm 210. A first end 201 of the base diaphragm 210 is coupled to (eg, bonded to) the pad of the first substrate 110, such that the COF package is electrically coupled to the display panel 100. The base diaphragm 210 includes a first surface and a second surface that are opposite to each other, and the integrated circuit chip 220 is formed at a central position of the first surface. The integrated circuit chip 220 is configured to receive a driving power and a driving signal of the PCB via the connector 400, to generate a gate signal and a data signal according to the driving power and the driving signal, and to output the gate signal and the data signal to the display panel 100 via the first end of the base diaphragm 210.

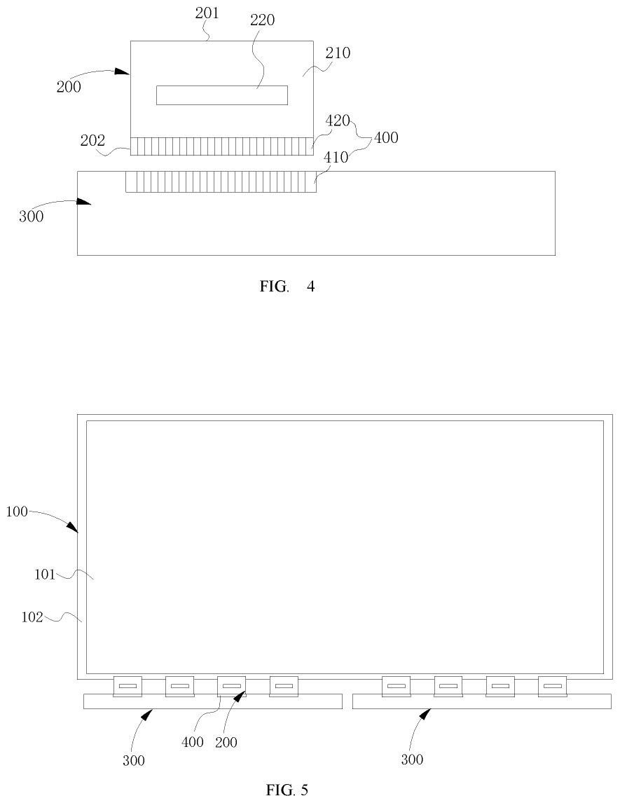

In one embodiment, as shown in FIG. 4, the connector 400 includes a male connection member 410 and a female connection member 420 fitting each other to form pluggable connection. The female connection member 420 is connected at a second end 202 of the COF package. The male connection member 410 is connected at one end of the PCB opposite to the COF package. As shown in FIG. 1 and FIG. 3, the connector 400 may also adopt another structure, that is, the second end 202 of the COF package is provided with the male connection member 410, while the end of the PCB opposite to the COF package is provided with the female connection member 420. By the fitting and pluggable connection between the male connection member 410 and the female connection member 420, the assembling and disassembling of the driver chip package 200 and the circuit board 300 are achieved. Such assembling/disassembling design is convenient for operation, and is not prone to cause damage to the driver chip package 200 or the circuit board 300 during the assembling and the disassembling.

In one embodiment, as shown in FIG. 1, the female connection member 420 includes bosses 230 arranged at a surface of the second end 202 of the COF package. The bosses 230 are configured to be inserted into the male connection member 410, in this way, the bosses 230 can be inserted into the male connection member 410 to realize the electrical connection. When the PCB needs to be modified, the male connection member 410 can be pulled out from the second end 202 of the COF package, and then the PCB is pulled out from the male connection member 410, thereafter, the new PCB is inserted into the male connection member 410, and finally the male connection member 410 is further inserted into the second end 202 of the COF package, the operation is simple without damaging the components.

In one embodiment, a plurality of the bosses 230 are arranged at the second end of the COF package 202 and equally spaced apart. A section of each of the plurality of bosses 230 is rectangular or approximately rectangular. The plurality of the bosses 230 as a whole form the female connection member 420, and are all inserted into the male connection member 410.

In one embodiment, the second end of the COF package 202 defines therein at least one notch 240, a projection 240 is arranged at a position of the male connection member 410 corresponding to a position of the respective notch 240, and the projection 411 snap-fits into the respective notch 240. The snap-fitting of the projection 411 into the notch 240 makes the pluggable assembling of the female connection member 420 and the male connection member 410 much stable and not prone to be loosened.

In the embodiment, two sides of the second end 202 in a width direction are symmetrically provided with the notches, and inner walls of two sides of the male connection member 410 are convex to form the protrusions at positions corresponding to the positions of the notches 240.

In one embodiment, a section of the respective notch 240 of the second end 202 may have a rectangular shape, an arc shape, or other regular shapes. In particular, semicircular notches may be symmetrically arranged at two sides of the second end 202, the second end of the COF package 202 can fit into the male connection member 410 to for pluggable connection through the notches 240, so that a stable structure can be formed after the second end of the COF package 202 fits into the connector 400.

In another embodiment, as shown in FIG. 3, the connector includes: a female connection member 420 arranged at one end of the circuit board 300 opposite to the driver chip package 200, and a male connection member 410 arranged at the second end 202 of the driver chip package 200. The male connection member 410 and the female connection member 420 are configured to fit each other to form pluggable connection.

In one embodiment, a surface of the circuit board 300 is provided with bosses, and the bosses are configured to be inserted into the male connection member 410. In this way, the bosses and the male connection member 410 realize the electrical connection. When the circuit board 300 needs to be modified, it is only required to pull the circuit board 300 out from the male connection member 410, then a new circuit board 300 is inserted into the male connection member 410, and it is not necessary to replace with new display panel. The operation is therefore very convenient, and the utilization of the products is improved.

In one embodiment, as shown in FIG. 5, the display assembly 10 includes a plurality of circuit boards 300, and a plurality of driver chip packages are arranged between each of the plurality of circuit boards 300 and the display panel and spaced apart from one another, that is, the respective driver chip package and the circuit board 300 are connected via one connector 400, and after pluggable connection of all the connectors 400 are completed, the electrical connection between the driver chip package 200 and the circuit board 300 is realized.

In one embodiment, the plurality of the circuit boards 300 may be arranged at the same side of the display panel 100 and equally spaced apart from adjacent ones.

In one embodiment, one side of the first substrate 110 where the protruding portion is located is provided with two PCBs, four driver chip packages 200 are arranged between each of the two PCBs and the display panel 100, and the respective driver chip package 200 is electrically connected with the circuit board 300 via the respective connector 400 so as to drive the display panel 100.

In one embodiment, the four driver chip packages 200 may be equally spaced in the same PCB.

One embodiment of the present application provides a display device including a display assembly 10. As shown in FIG. 1 and FIG. 5, the display assembly 10 includes a display panel 100, a plurality of the circuit boards 300, a plurality of connectors 400, and a plurality of COF packages. The display panel 100 includes a display area 101 and a peripheral circuit area 102 surrounding the display area 101, and the peripheral circuit area 102 is provided with a driver circuit configured to drive the display panel 100. The plurality of COF packages are arranged between the circuit boards 300 and the display panel 100 and are spaced apart from one another. The respective COF package has a first end 201 and a second end 202 that are opposite to each other, the first end 201 is in electrical connection with the driver circuit of the peripheral circuit area 102, and the second end 202 is in connection with the circuit board 300 via one of the connectors 400, that is, at least one COF package is connected between each of the plurality of circuit boards 300 and the display panel 100, and the respective COF package is in pluggable connection with the circuit board 300 via the respective connector, whereby realizing the electrical connection. For example, in a display device with a TFT-LCD, when the circuit board 300 needs to be modified, the circuit board 300 is pulled out from the connectors 400, and the new circuit board 300 is inserted into the connectors 400, which is convenient to be operated and does not need to replace with new display panel for assembly, thereby greatly improving product utilization.

The display device provided by this embodiment of the present application may be any product or component with display functions, such as a mobile phone, a tablet computer, a television, a display, a notebook computer, a digital photo frame, a navigator, and the like.

The above description is only optional embodiments of the present application, and is not intended to limit the present application. Any modifications, equivalent substitutions, and improvements made within the spirit and principles of the present application are included in the protection scope of the present application.

What is claimed is:

1. A display assembly, comprising:
a display panel, comprising: a display area and a peripheral circuit area arranged at an outer periphery of the display area; wherein the peripheral circuit area is provided with a driver circuit;
a driver chip package, the driver chip package having a first end and a second end that are opposite to each other, and the first end being in electrical connection with the driver circuit;
a circuit board; and
a connector;
wherein the circuit board is in connection with the second end of the driver chip package via the connector.

2. The display assembly of claim 1, wherein the connector comprises: a female connection member, connected at the second end of the driver chip package; and a male connection member, connected at one end of the circuit board opposite to the driver chip package; and the male connection member and the female connection member are configured to fit each other to form pluggable connection.

3. The display assembly of claim 2, wherein the female connection member comprises bosses arranged at a surface of the second end, and the bosses are configured to be inserted into the male connection member for electrical connection.

4. The display assembly of claim 2, wherein the second end defines therein at least one notch, a projection is arranged at a position of the male connection member corresponding to a position of the respective notch, and the projection snap-fits into the respective notch.

5. The display assembly of claim 4, wherein the at least one notches are symmetrically arranged at two sides of the second end in a width direction.

6. The display assembly of claim 4, wherein a section of the respective notch is arc.

7. The display assembly of claim 6, wherein a section of the respective notch is semispherical.

8. The display assembly of claim 4, wherein a section of the respective notch is rectangular.

9. The display assembly of claim 1, wherein the connector comprises: a female connection member, arranged at one end of the circuit board opposite to the driver chip package; and a male connection member, arranged at the second end of the driver chip package; and the male connection member and the female connection member are configured to fit each other to form pluggable connection.

10. The display assembly of claim 9, wherein the female connection member comprises bosses arranged at a surface of the circuit board, and electrical connection between the driver chip package and the circuit board is realized through the fitting and the pluggable connection between the bosses and the male connection member.

11. The display assembly of claim 1, wherein the display assembly comprises a plurality of the circuit boards, and a plurality of the driver chip packages are arranged between the respective circuit board and the display panel.

12. The display assembly of claim 11, wherein the plurality of the driver chip packages are equally spaced apart at the same circuit board.

13. The display assembly of claim 11, wherein the plurality of the circuit boards are arranged at the same side of the display panel and equally spaced apart from adjacent ones.

14. The display assembly of claim 1, wherein the driver chip package is a chip-on-film package.

15. The display assembly of claim 1, wherein the driver chip package is a tape carrier package.

16. The display assembly of claim 1, wherein the display panel is a thin film transistor-liquid crystal display, an active matrix liquid crystal display, a surface conduction electron emitter display panel, a plasma display panel, or an organic luminescence display panel.

17. A display device, comprising:
a display panel, comprising: a display area and a peripheral circuit area arranged at an outer periphery of the display area; wherein the peripheral circuit area is provided with a driver circuit;
a driver chip package, the driver chip package having a first end and a second end that are opposite to each other, and the first end being in electrical connection with the driver circuit;
a circuit board; and
a connector;
wherein the circuit board is in connection with the second end of the driver chip package via the connector.

18. A display device, comprising:
a display panel, comprising: a display area and a peripheral circuit area surrounding the display area; wherein a surface of the peripheral circuit area is provided with a driver circuit;
a plurality of chip-on-film packages, with each chip-on-film package having a first end and a second end that are opposite to each other, and the first end being in electrical connection with the driver circuit;
a plurality of circuit boards; and
a plurality of connectors;
wherein
at least one of the plurality of chip-on-film packages is connected between the respective circuit board and the display panel; and
the second end of each chip-on-film package is connected with the respective circuit board via the respective connector.
